(19) United States
(12) Patent Application Publication
(10) Pub. No.: US 2016/0138155 A1
(43) Pub. Date: May 19, 2016

(54) PROCESS FOR OBTAINING METAL OXIDES BY LOW ENERGY LASER PULSES IRRADIATION OF METAL FILMS

(71) Applicant: Centro de Investigación Cientifica y de Educación Superior de Ensenada, Baja California, Ensenada (MX)

(72) Inventors: Santiago CAMACHO LÓPEZ, Ensenada (MX); Marco Antonio CAMACHO LÓPEZ, Ensenada (MX)

(73) Assignee: Centro de Investigación Cientifica y de Educación Superior de Ensenada, Baja California, Ensenada (MX)

(21) Appl. No.: 14/977,096

(22) Filed: Dec. 21, 2015

Related U.S. Application Data
(62) Division of application No. 13/715,568, filed on Dec. 14, 2012.
(60) Provisional application No. 61/576,523, filed on Dec. 16, 2011.

(51) Int. Cl. C23C 14/58; C23C 14/35

(52) U.S. Cl. CPC C23C 14/5813; C23C 14/5853; C23C 14/35

(57) ABSTRACT

The present invention relates to processes for obtaining metal oxides by irradiation of low energy laser pulses of metal layers, wherein said metals can be formed as simple metals, alloys, or multilayers. The present invention performs the oxidation of a thin metal film deposited on a substrate; e.g., glass (SiO₂) or silicon (Si) by a laser-irradiation time of a few nanoseconds to femtoseconds at high repetition rate, time necessary to achieve a stoichiometry and a well-defined microscopic structure. Through the processes of the invention, it is possible to obtain complex structures and metal oxides at room temperature in a very short time and with very low energy consumption.

### CROSS REFERENCE OF RELATED APPLICATION

This application claims the benefit under 35 U.S.C. §119(e) of the filing date of non-provisional patent application Ser. No. 61/576,523 filed Dec. 16, 2011, which is incorporated herein by reference.

### FIELD OF THE INVENTION

The present invention relates to methods for obtaining metal oxides, particularly to methods for obtaining metallic oxides by low energy laser pulses irradiation of metal films, wherein said metals can be formed as simple metals, alloys, or multi-layers.

### BACKGROUND OF INVENTION

Obtaining metal oxide thin films is generally accomplished by the thermal treatment of metal films deposited on any type of substrate. Here, all the metallic material, which is initially in the substrate, is transformed into metal oxide. This method is known as thermal oxidation, which can be performed, for example, by using a furnace, where the heat treatment of the metal layers is performed under oxidizing atmosphere (Ting and col.¹).

However, by using a continuous wave laser or pulsed-laser and a suitable atmosphere it is also possible to obtain structural and composition changes in the metals. This method is characterized by carrying out the processing only in a well-localized region of the material, determined by the laser characteristics and physical properties of the material.

For example, the oxidation of titanium has been reported by using a Nd:YAG (1064 nm) continuous wave laser (Perez del Pino and col.²), and the oxidation of chrome films using nanosecond (ns) pulses of a Nd-YAG laser (Qizhi and col.³). The structural and photoluminescent properties in periodic structures induced in a ZnO crystal by a femtosecond (fs) laser pulses have also been reported (Guo and col.⁴).

Furthermore, among the existing patent documents in the state of the art, the US patent U.S. Pat. No. 6,365,027⁵, describes a method for generating an electrodeposited film that comprising irradiate with a laser pulse whose pulse length is less than a picosecond, at least one part of the surface of a substrate to be treated with such laser pulse, to form a laser irradiated region, wherein the electrode used are Au, Cu, Pt, or Zn.

The patent application KR20120000422⁶ describes a method for the formation of nano-structures of uniform thickness without organic materials by deposition of laser pulses, using a substrate into a reaction chamber; the substrate is used at room temperature or at a one temperature lower than 300° C.; later metal oxides of interest are deposited in the substrate by the method of laser deposit to form nano-structures on the substrate. For the formation of nano-structures, the laser pulse repetition frequency is maintained for 500 minutes between 1 and 10 Hz at a temperature up to 300° C. The obtained composition of the nano-structures is the same as the initial metal oxides, including titanium dioxide, zinc oxide, tin dioxide, niobium oxide and oxide of tin zinc.

The patent application JP2006276757⁷ describes a thin film system consisting of alternating thin layers of metal and metal oxide for optical devices; the system comprises two or more laminated layers of a metal oxide film and a metal laminated film. Specifically, the metal film consists of a material whose standard electrode potential is lower than that of the metal constituting the metal oxide film; this creates a heterogeneous phase whose refractive index is different from the refractive index induced by a short laser pulse.

The patent application EP0273547⁸ describes a method for producing a thin layer of amorphous metal by the metallurgical bond of a thin film of pre-amorphous metal on a metallic substrate that has a large number of thermal distortions, applying full or selective irradiation by laser pulses in the thin film of pre-amorphous metal. The part irradiated by laser pulses becomes amorphous by rapid heating and cooling, thus obtained the entire surface or portion thereof as an amorphous layer; subsequently a porous amorphous metal layer is obtained after acid treatment and removing the non-amorphous part.

Although it is possible to obtain metal oxides by the above methods in the cited patents, such methods use high-energy laser pulses in the order of milliseconds, while having at the same time serious limitations as to obtain metal oxides of very diverse and complex structures. Thus, the application of the obtained oxides is limited.

Therefore, it is necessary to provide methods for obtaining metal oxides that use low power laser while generating at the same time more complex and diverse metal oxides, which increases the chance of producing materials with better thermal, electrical and optical properties.

### SUMMARY OF THE INVENTION

### Objectives of the invention

One objective of the present invention is to provide processes of low energy laser and short laser pulses, for obtaining metal oxides by irradiating deposited films or metallic layers on crystalline and amorphous substrates with laser pulses, being the pulse duration between nanoseconds (ns) and femtoseconds (fs), and at a very high repetition frequency.

Another objective of the present invention is to provide metal oxides of crystalline, amorphous, or crystalline-amorphous structure by using low energy femtosecond laser pulses.

Another objective of the present invention is to provide processes for the oxidization of a thin metal layer, deposited on a substrate, by a very short laser irradiation time compared with that of a heat treatment in a conventional treatment, to achieve the stoichiometry and a well-defined microscopic structure of the oxides obtained.

### BRIEF DESCRIPTION OF THE DRAWINGS

The patent or application file contains at least one drawing executed in color. Copies of this patent or patent application publication with color drawing(s) will be provided by the Office upon request and payment of the necessary fee.

FIG. 1 Shows a schematic diagram of the experimental setup for pulsed laser irradiation of metal films, according to the present invention.

FIG. 2 Shows (a) X-ray diffractogram and (b) SEM micrograph corresponding to the as-deposited on fused silica molybdenum thin films.

FIG. 3 Shows an optical image of a femtosecond laser irradiated (eight scans) trace on a molybdenum thin film. The dashed circles show the regions probed by the laser in the micro-Raman spectroscopy experiment.

FIG. 4 Shows the micro-Raman spectra corresponding to the colored regions shown in FIG. 3. One can observe (a) as-deposited Mo thin film (zone III of FIG. 3); (b) light-gray region at the center of the trace (zone I of FIG. 3); (c) dark-green stripe (zone II in FIG. 3) besides of the light-gray zone. The peaks marked with an asterisk (*) have been earlier reported by Mestl and col. for MoO₃⁹.

FIG. 5 Shows SEM photomicrographs of a laser exposed molybdenum thin film. One can observe (a) a single scan laser exposure with an on target per pulse fluence of 0.03 J/cm²; where ablation occurs at this fluence; (b) five scans of laser exposure, evidencing the grain structure formed to the sides of the track generated by ablation; (c) the same five scans of laser exposure on the edge of the scanned region, which notes the absence of ablation signs and the potentiation of the formation of the grain structure.

FIG. 6 Shows a bismuth layer irradiated with the process of the present invention by ns laser pulses. It notes the presence of periodic structures in the surface.

FIG. 7 Shows a SEM micrograph of a thin film of molybdenum, displaying rightwards the region treated with the process of the present invention by irradiation of ps laser pulses.

FIG. 8 Shows (a) an optical micrograph of a Zn layer where it can observe the affected area by the process of the invention by irradiation of fs laser pulses, displaying a ring pattern (I, II, and III); and (b) micro-Raman spectra corresponding to positions I, II, and III as described in the above optical micrograph.

### DETAILED DESCRIPTION OF THE INVENTION

The present invention relates to processes at room temperature for obtaining metal oxides by irradiation with laser pulses of metallic films or layers deposited on crystalline or amorphous substrates, where the pulse duration is between nanoseconds (ns) and femtoseconds (fs) so that the energy associated with said irradiation is very low. The metal layer is constituted, for example, of transition metals, transition metal alloys, or multilayers thereof. By the present invention, it is possible to obtain complex metal oxide structures using low energy femtosecond laser pulses and at very high repetition frequency.

The process of the present invention allows to obtain metal oxides by the laser irradiation of metallic layers, where said metals can be formed as simple metals, for example, including transition metals, alloys, or multilayers thereof, wherein the oxidation of the metallic thin layer is carried out deposited on a substrate; e.g. glass (SiO₂), or silicon (Si) by a laser irradiation time of a few seconds, the time necessary to achieve the stoichiometry and a well-defined microscopic structure of the material obtained.

The process of oxidation induced by ultrashort laser pulses of the present invention allows performing the oxidation of a thin metal layer deposited on a substrate such as glass (SiO₂), or silicon (Si). The process comprises carrying out the irradiation of the metal layer using laser pulses whose duration may be of some nanoseconds, some tens of picoseconds, or a few tens of femtoseconds. The irradiation process is performed in an air or oxygen atmosphere and can be done at a fixed point on the metal layer of interest. It is also possible to perform a linear laser scanning or any other geometry on the metallic layer intended to oxidize. Thus, patterns can be produced in different geometries, including complex patterns constituted by the metal oxide. Until the present invention, it was not possible to obtain this type of patterns, not even by the thermal oxidation technique widely known in the art.

The irradiation result of the metal layer by the process of the present invention is to obtain an irradiated metal oxide, where the stoichiometry of the obtained oxide and its amorphous or crystalline form strongly depend on the laser irradiation conditions, such as pulse fluency and integrated fluency, pulse duration, peak intensity, and repetition frequency.

For purposes of the present invention, the laser irradiation time necessary to achieve the stoichiometry and a well-defined microscopic structure is of a few seconds, a very short time compared to the processing time required to reach the stoichiometry and a well-defined microscopic structure by conventional methods; e.g., thermal treatment furnace, which can take several hours in obtaining the desired results.

Given the characteristics inherent in laser-processing materials, a very well-defined area in the irradiated zone of the desired metal layer is established (corresponding to the laser beam-waist on the surface of the layer), which acts as a source of punctual heat and as a located electric field. By diffusion effects, the heat generated in the directly laser-irradiated zone, propagates with radial symmetry to the periphery, creating a temperature gradient in a region larger than the one directly illuminated by the laser beam.

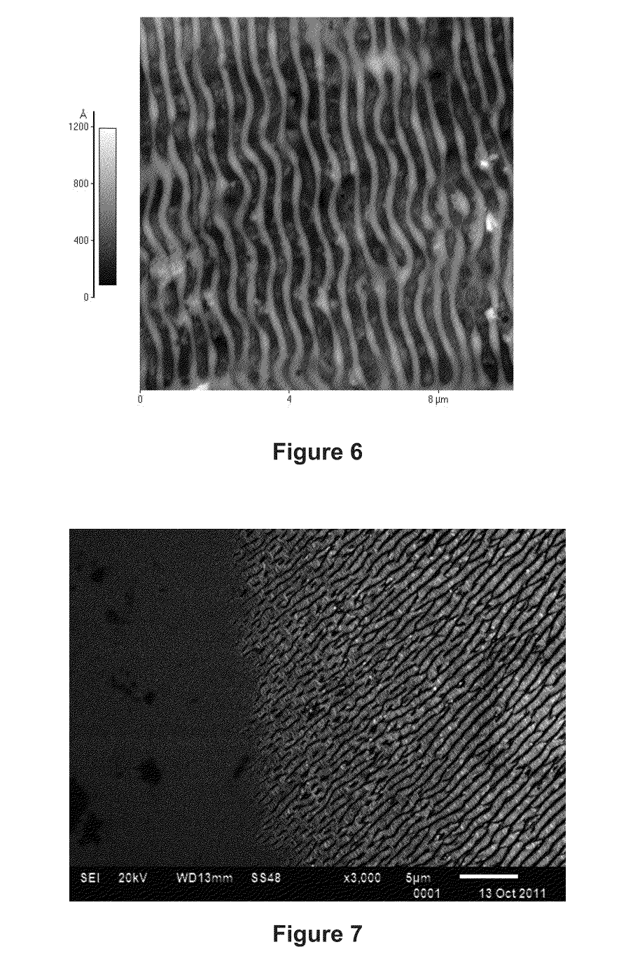

When the process of obtaining metal oxides induced by laser irradiation of the present invention involves nanosecond or picosecond pulses in the metal layers, it allows obtaining crystalline metal oxides (FIGS. 6 and 7). Moreover, periodic structures can be obtained at the surface (FIG. 6), so that optical elements can be fabricated as diffraction gratings using such materials. The formation and characteristics of the periodic structures on the surface depend on irradiation parameters as wavelength, polarization, laser fluence, and number of laser pulses.

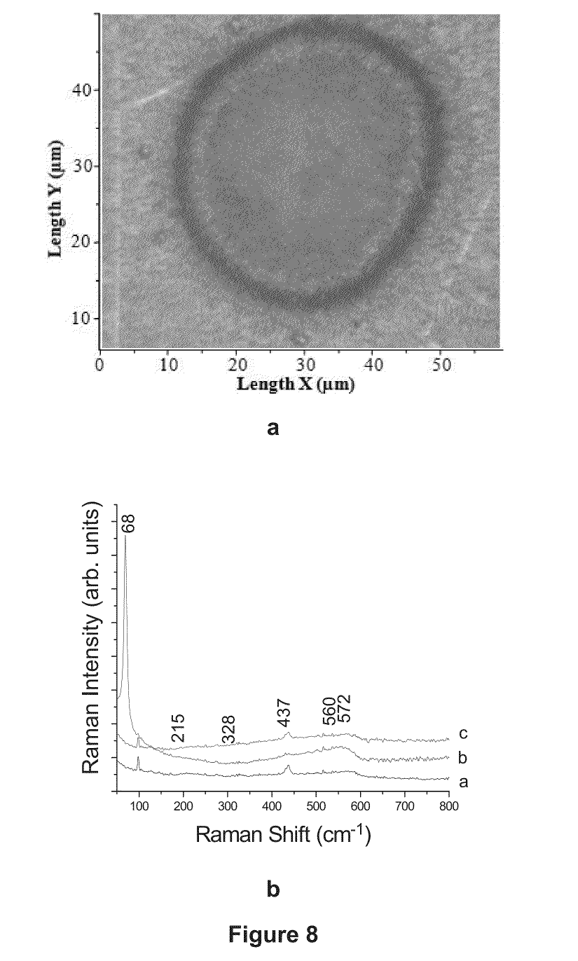

When the process of obtaining metal oxides induced by laser irradiation of the present invention involves femtosecond pulses in metal layers, this allows, in a unique way and unlike any other manufacturing technique of metal oxides known in the art, the obtaining of micro or nanostructured patterns of metallic oxides (FIG. 8), wherein each micro or nano structure can have a specific stoichiometry and an amorphous, crystalline or amorphous-crystalline phase, well defined and distinct from its neighboring structure. Therefore, is obtained the formation of different metal oxides whose stoichiometry and structure are according with the temperature profile set in the irradiated region and its vicinity; thus, a ring pattern (fixed point irradiation case), or a stripped pattern (scanning irradiation case) is differentially obtained, whose stoichiometry and structure differ from ring to ring, or from strip to strip (FIG. 8). Typical dimensions of the rings and the strips composing an oxide pattern induced by femtosecond laser are tens of micrometers in diameter and between 2 and 5 micrometers wide, whereas in turn, each ring consists of nanostructured morphology.

According to the present invention, the metal layers for generating the oxides described here can be formed by any element in the periodic table identified as metallic element; e.g., transition metals of the group comprising transition metals belonging to the groups III B or scandium family (Sc, Y), IV B or titanium family (Ti Zr, Hf) V B or vanadium family (V, Nb, Ta), VI B or chromium family (Cr, Mo, W), VII B or manganese family (Mn, Tc, Re), VIII B or iron family (Fe, Ru, Os), IX B or cobalt family (Co, Rh, Ir), X B or nickel family (Ni, Pd, Pt), I B or copper family (Cu, Ag, Au), II B or zinc family (Zn, Cd, Hg), metals of the III A group (Al, Ga, In, Tl), metals of the IV A group (Ge, Sn), metals of the V A group (Bi), or combinations thereof, which may be in the form of simple metals, alloys, or multilayers. In this sense, although any of these metals can be used for the purposes of the present invention, the preferred metals are molybdenum (Mo), titanium (Ti), bismuth (Bi), tungsten (W), iron (Fe), tin (Sn), zirconium (Zr), vanadium (V) and indium (In).

According to the present invention it is possible to obtain oxides of the mentioned metals with complex structures, which have interesting properties for use in multiple applications, such as solid state sensors, semiconductors, transparent electrodes, and optical devices. Generally, the metal oxides obtained by the process described herein can have very fine patterns, for example, fine patterns of m-MoO₂, or non-stoichiometric as Mo₄O₁₁ and even crystalline phase of a-MoO₃ in case of obtaining molybdenum (Mo) oxides, while for other metals such as Ti, W, Sn, Bi, Zn it is possible to obtain patterns of TiO₂, WO₃, SnO₂, Bi₂O₃, ZnO. As shown, the processes of the present invention allow to obtain metal oxides with various structures, which exhibit improved micro and nanostructures features that can be controlled by the laser irradiation parameters, which gives these oxides great advantages compared with metal oxides obtained by thermal heating or by continuous emission lasers.

It is important to point out the advantages of the ultrafast (ultrashort pulse) laser-processing technique over the conventional thermal treatment for obtaining metallic thin film oxides. In general, metal oxides can be produced by using conventional furnaces and atmospheric air, where usually several hours of thermal heating at different temperatures are necessary to achieve a given type of oxide and crystalline structure^{1, 10, 11, 12}. When using this thermal heating technique, for example with metallic thin films, the whole sample is homogeneously oxidized. Lasers on the contrary allow a very fast and spatially well-defined confinement for temperature rising; if using laser pulses, the heat deposition and consequently the temperature rise occurs within the pulse duration, making it possible to rapidly oxidize a metal when exposing it to a long enough single pulse or to a series of short laser pulses^{13, 14}.

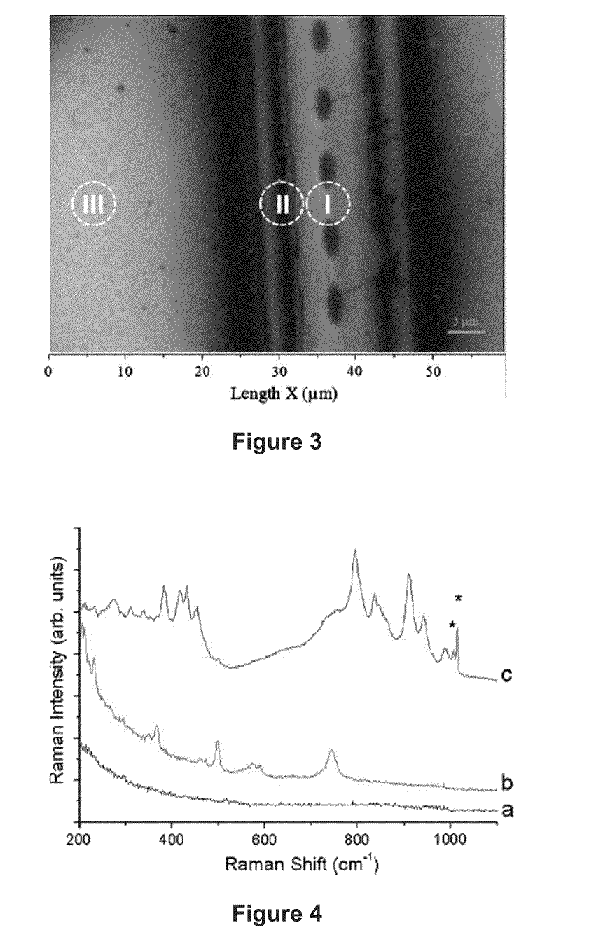

Furthermore, lasers possess a wide selection of parameters to finely tune and controlling a chemical reaction, such as metal oxidation. For instance, it is possible to choose the right single pulse fluence to achieve a desired peak temperature while, on multiple pulse exposure, the pulse repetition rate drives heat accumulation effects^{14, 15} and therefore, the average temperature which would lead to a specific stoichiometry and a distinctive crystalline phase in the case of laser-induced metallic oxides. Also, due to heat diffusion effects, it is possible to obtain a lateral heat distribution, which gives place to a complex structure of different stoichiometry and crystalline phases across the laser affected area and beyond (FIG. 3).

For purposes of the invention, if the laser beam is focused strongly on the sample, it is possible to obtain very fine micro patterns or even nano patterns. For the particular case of ultrashort pulses (femtosecond) at very high repetition rates (MHz), quite low energies and a beam focusing strongly, allow obtain high enough fluences and heat cumulative effects, in such a way that the necessary temperatures, over a few seconds exposure, to obtain very fine patterning of the m-MoO₂, the non-stoichiometric o-Mo₄O₁₁, and even the crystalline phase of α-MoO₃. All the above demonstrates the dramatic advantages of the ultrashort pulses and the high repetition rate laser-induced oxidation of metallic thin films as compared to the conventional thermal oxidation technique.

For purposes of the present invention, the laser pulses applied to the metallic layer or film can be of nanoseconds (10⁻⁹ s), picoseconds (10⁻¹² s), or femtoseconds (10⁻¹⁵ d), while the laser pulses can be deposited using a high repetition rate in a range of 1 kHz to 100 MHz. Therefore, the energy associated to these pulses is very low, which becomes of microJoules (μJ) to nanoJoules (nJ) per pulse, preferably between 1 to 10 nJ per pulse.

As a result of the laser irradiation on the metal layers by the process of the present invention, it is possible to obtain metal oxides with dielectric, semi conductive, or conductive properties. These electrical conductive properties depend on and can be modulated modifying the laser irradiation conditions of the initial metal layer as described here. Therefore, the resulting metal oxides can find applications in areas as for example photocatalysts, transparent electrodes, gas sensing, electro-chromic and photo-chromic devices, and as semiconductors in the transistor industry.

According to the present invention, experiments were conducted for example on femtosecond (fs) laser-induced oxidation of molybdenum (Mo) thin films. The Mo thin films were deposited on fused silica substrates by the magnetron DC-sputtering technique. The as-deposited thin films were characterized by X-ray diffraction, finding that as-deposited molybdenum has a crystalline bbc form. The films were irradiated at atmospheric air, using a femtosecond laser Ti: Sapphire (wavelength centered at 800 nm, pulse duration of 60 fs, 70 MHz repetition frequency, and an energy up to 9 nJ per pulse). The thin Mo films were laser scanned in the form of several millimeters long straight-line traces by using a fluence per pulse laser below the ablation threshold of Mo. We used an optical microscope (OM) and scanning electron microscope (SEM) to study the laser-induced optical and morphological changes on the exposed region. Energy dispersive spectrometry (EDS) and micro-Raman spectroscopy (MRS) were used to determine the degree of oxidation and the phase change across the laser-irradiated paths on the thin film of Mo.

The following example, and its various stages, is included with the only purpose of illustrating the present invention, and should not be construed as limiting the scope of the invention.

### EXAMPLE

Deposition of Mo Thin Film.

Mo thin films were deposited by using the magnetron DC-sputtering technique. A disc of molybdenum (99.9% Lesker) was used as target and argon ions to erode it. Molybdenum was deposited on fused silica substrates at room temperature. The deposition parameters were power 150 W, argon gas 18 sccm, pressure 0.48×10⁻³ mBar, and a deposition time of 6 min. The as-deposited molybdenum thin films were characterized by XRD (Siemens D-5000 diffractometer with a radiation source of Cu Kαλ=1.5406 Å) and SEM. The thickness of the films (500 nm) was measured by profilometry and confirmed by SEM analysis.

Irradiation of Mo Thin Films With Laser Pulses.

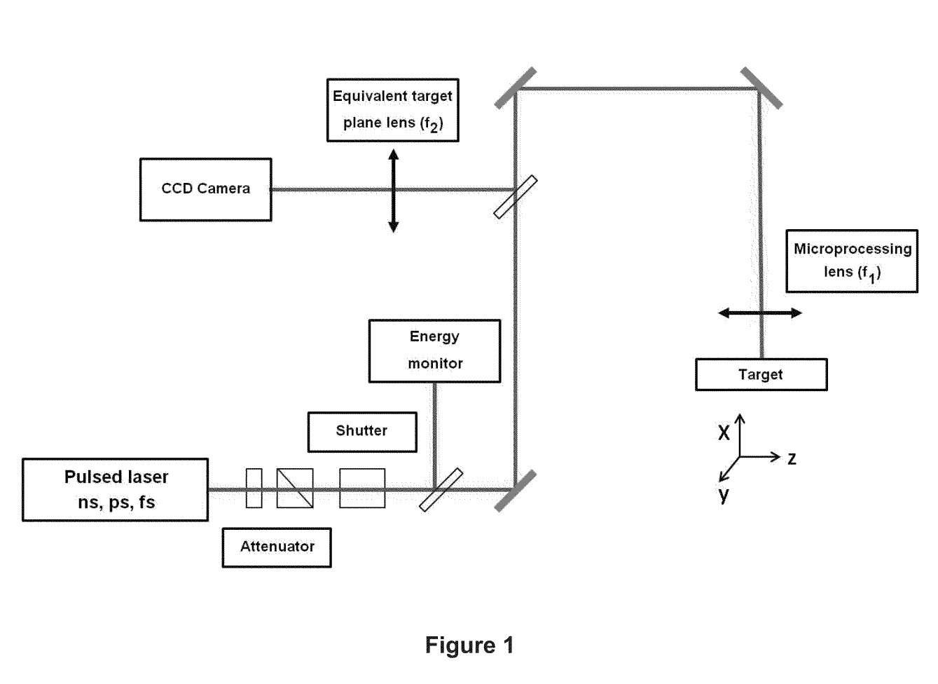

We used a Ti: Sapphire laser oscillator with output pulses of 60 fs, an energy per pulse of 6.5 nJ, and its wavelength centered at 800 nm for irradiating the Mo thin films at a repetition frequency of 70 MHz. We performed the laser irradiation of the films, at atmospheric air, at normal incidence and focusing the laser beam with an aspherical lens (NA=0.5) of 6 mm focal length. Because the laser beam is slightly elliptical, the focused beam waist is elliptical with a major and minor axis of 3 to 5 microns, respectively. The films were conveniently mounted on a computer controlled XYZ linear stage. FIG. 1 shows a schematic diagram of the experimental set up.

The films were laser exposed in the form of a series of straight-line traces a few millimeters long, the scan speed was kept fixed at 530 μm/s. We used an on target (delivered) per pulse energy of ˜2.4 nJ and therefore per pulse delivered fluence of ˜0.03 J/cm². The on target-integrated fluence was determined and controlled by the scan speed and the number of scans performed along the same path. The ablation threshold fluence for 500 nm thick Mo film, deposited on glass was of 0.11 J/cm² under 800 nm, 100 fs laser pulse irradiation.

Characterization of the Irradiated Regions of the Mo Thin Films.

The transformed traces on the molybdenum films were analyzed by optical microscopy (Olympus BX-41 microscope) to identify texture and color changes. SEM and EDS (Philips XL-30 microscope) were used to study the surface for morphology and stoichiometric changes, respectively; micro-Raman spectroscopy (HR-800-LabRam) was used to identify the laser induced molybdenum oxide type and its crystalline phase. On the micro-Raman technique the backscattering configuration was used to analyze the laser exposed areas on the Mo films. A linearly polarized mW He-Ne laser (632.8 nm) was used as the excitation source. The He-Ne beam was focused down to a 2 μm diameter spot by using a 100× microscope objective mounted on an Olympus BX-41 microscope.

The experimental scheme described here applies to any of the transition metals listed in this document. The only variation on the type of transformation to be achieved in the starting material is the laser pulse duration from ns, ps, or fs. This implies the use of either a solid state laser Nd:YAG (for ns or ps), or the solid state laser Ti:Sapphire (for fs). The cases presented in FIGS. 6 and 7 are achieved with laser pulses at a repetition rate of Hz to kHz.

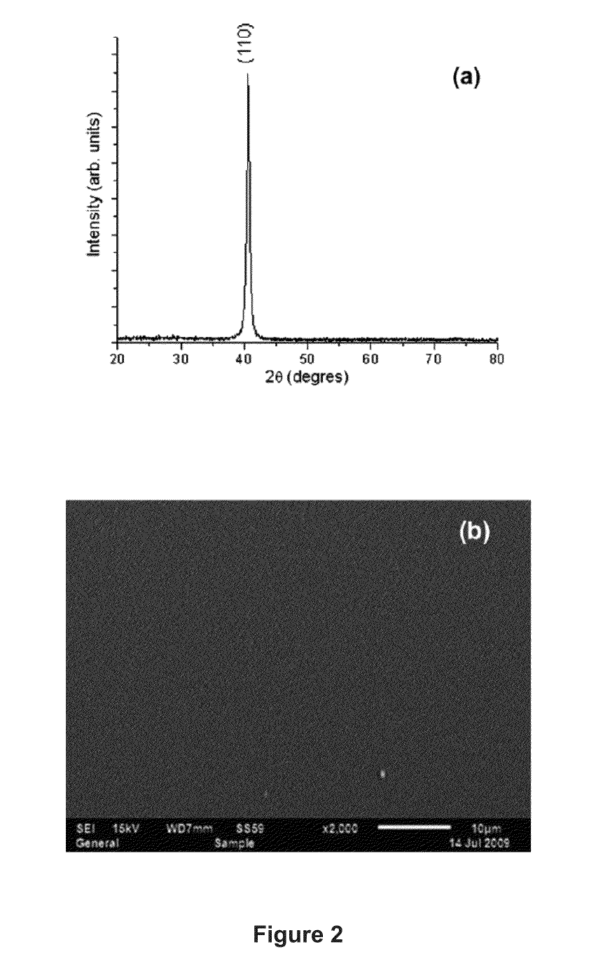

FIG. 2 shows the X-ray diffractogram (a) and a SEM micrograph (b) of an as-deposited molybdenum thin film. A single peak centered at 2θ=40.6° is present in the diffractogram, which correspond to the reflection of the plane (1 1 0). This indicates that the molybdenum grew preferentially in the direction of such a (1 1 0) plane. As one can observe in the SEM micrograph 2b the thin film surface has a uniform and homogeneous texture.

FIG. 3 shows an image acquired with the optical microscope coupled to the micro-Raman system. The optical image corresponds to a fs laser irradiated trace with eight scans along the same trace. As shown, there is a clear laser-induced texture and a complex coloration (from center of the trace outwards: light-gray, light-green, dark-green, blue, dark-brown, and light-brown) in the vicinity of the directly exposed path (˜3 μm wide), which actually corresponds to the zone that contains the sharply ablated elliptical spots along the center. The texture and coloration is related to the degree of oxidation and crystalline phase of the molybdenum given by the cumulative temperature gradient established by the laser heat deposition and the diffusion process during the exposure. We must point out here that the thin film preserves the exact footprint (shape and size) of the laser beam waist, which is characteristic for ablation with fs laser pulses. Therefore, there is a clear evidence of two distinct physical mechanisms of light-matter interaction; on the one hand the ultrashort pulse laser ablation nature, and on the other hand the thermal component provided by the long envelope of the MHz pulse train used in the exposure.

FIG. 4 shows the Raman spectra that correspond to the as-deposited molybdenum thin film and the spectra corresponding to the fs laser irradiated traces. In order to obtain the structure of the material in each region with different color, the spectra were obtained by using a low power He-Ne laser (1.2 mW, 10 kW/cm²), this is so for serving the purpose to avoid inducing any additional structural changes in the probed material while running the Raman characterization. It is worth noting that no additional transformation was observed, in the fs-laser-irradiated material, during Raman characterization runs even for higher probing He-Ne laser power. The spectrum 4a correspond to the as-deposited molybdenum thin film (zone III, FIG. 3); as it is expected for all metals no Raman peaks are present. FIG. 4b shows a representative Raman spectrum taken at the center of a fs-laser irradiated trace (zone I, FIG. 3). One can observe that the spectrum 4b is constituted by several peaks located at 204, 209, 231, 347, 351, 366, 425, 461, 471, 498, 571, 588 y 744 cm⁻¹, in good agreement with the Raman spectrum of the m-MoO₂ phase reported for single crystal by Srivastava and Chase¹⁶, powder by Camacho-Lopez and col.¹⁷, and thin films by Spevack and McIntyre¹⁸. This result indicates that the molybdenum thin film transforms into m-MoO₂ after low energy-high repetition rate fs-laser irradiation. In this manner, the irradiated molybdenum suffers an oxidation process acquiring the monoclinic structure. EDS measurements (at the same zone I) confirmed the stoichiometric relation MoO₂. Raman spectrum 4c corresponds to the dark-green region (zone II, FIG. 3). Raman bands are located at 211, 275, 310, 339, 382, 416, 431, 455, 500, 745, 795, 836, 849, 862, 909, 941, 986 cm⁻¹. According to the work reported by Dieterle and col.¹⁹, Dieterle and Mestl²⁰, and Blume²¹, these Raman bands indicate that the material in the dark-green (zone II, FIG. 3) is constituted by the orthorhombic (o-Mo₄O₁₁) crystalline phase. Additional peaks marked with *, located at 1006 and 1014 cm⁻¹ are present in the spectrum 4c. These two peaks (at 1003 and 1012 cm⁻¹) have been previously reported by Mestl and col. for MoO₃²². They attribute those peaks to vibrational modes of Mo═O.

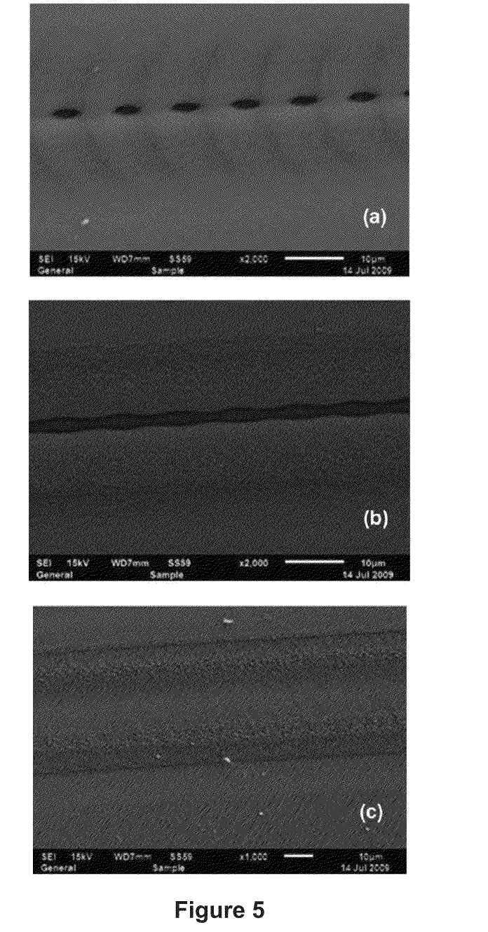

FIG. 5 shows SEM micrographs of laser-irradiated traces on the molybdenum thin films. As mentioned above, although we used an on target (per pulse) delivered fluence of ˜¼ the previously reported ablation threshold fluence on Mo thin films, a well-defined ablation effect can still be observed. This, because the scan is stopped at any point, then the number of pulses impinging on said fixed point is sufficient to accumulate an integrated fluence, which produces the ablation effect (see FIG. 5a). Therefore, we can conclusively state that the ablation threshold fluence for molybdenum thin films (deposited on fused silica substrates) under 800 nm, 60 fs laser pulses, is 0.03 J/cm². The most likely cause of the lower ablation threshold we observe here is the fact that, since we are using a multiple pulse exposure at a very high repetition rate, there are incubation effects involved; it is well known for different materials, including metals that this effect will lower down the ablation threshold^{23, 24}. In our case, the incubation effects are of thermal nature provided by the pulse train envelope used during the irradiation. A dominant effect in the interaction studied in the present invention is the laser heating given by the high repetition rate (MHz) delivery of pulses, which will produce heat accumulation and therefore, temperature rise. Nonetheless, given the ultrashort nature of every single pulse within the pulse train; it should be noted that there are reported works on lower ablation thresholds for metals, which are explained by multi-photon absorption processes^{25, 26}. The effect of performing an increasing number of scans along the same path is the growth of a couple of sideways tracks (FIGS. 5b and 5c) composed of scatter grains of ˜1 μm and smaller sizes. The SEM micrographs (see FIGS. 5a, 5b and 5c) show laser exposed paths to a single scan (FIG. 5a) and to five scans (FIGS. 5b and 5c); we must note that FIG. 5c shows one end of the trace exposed to five scans, and there are no ablation signs. The reason why laser ablation did not occur at one end of the path is that, for a millimeter long laser scan, and a very small Rayleigh range, the laser beam-waist eventually takes off or dives in the film surface. The above scenario makes the on target delivered fluence to fall (eventually below the ablation threshold), since the laser beam cross section intersecting the film surface is larger than the cross section of the beam-waist in either case. The laser beam-waist takes off or dives in the sample over a long scan because the sample does not run perfectly perpendicular to the laser incidence.

SEM of the laser-exposed traces reveals well-defined ablation spots, which are an exact footprint of the elliptically shaped laser beam waist (of 3 μm and 5 μm short and long axes) incident on the film. Notices that the elliptically shaped ablation spots (FIGS. 3 and 5a) are periodically distributed; this obeys to an unexpected software-electronic failure in our translation stage system that occurred during the laser irradiation, which caused the scan to pause periodically. So, the ablated spots correspond to the positions where the scan paused and therefore, those spots on the thin film were exposed to a larger number of pulses than everywhere else along the scan. This actually reinforces the explanation of the lower ablation threshold as a result of incubation effects, since the effect depends on the number of pulses, i.e. the exposure time.

We can also see how the effect of the laser irradiation extends as far as ˜25 μm sideways; these irradiated traces show grain regions, which correspond in the optical images to pattern colored fringes of different widths between 2 and 10 μm wide, caused by the temperature gradient established by the laser heat deposition and the heat diffusion perpendicular to the laser scan direction.

At present, we do not have a direct experimental method for estimating the temperatures achieved in the Mo thin film at different laser fluences. However, it is well known the range of temperatures at which the different Mo oxides reported in the present invention synthesize. For instance, MoO₂ and MoO₃ synthesize within the temperature range 800-1200 K^{27, 28}. Therefore, we can estimate that the metal oxides of the present invention are formed under a laser-induced heating profile (transversal to the laser scanning direction) and achieve the above average temperatures across the regions I and II (shown in FIG. 3) where we observe the formation of m-MoO₂ and o-Mo₄O₁₁. According to Floquet and col.²⁹ the MoO₂ forms at the highest temperature, therefore our results are consistent to such fact since the highest laser-induced temperature must be achieved at the center of the laser exposed region, i.e. along region I in FIG. 3; while a lower temperature should be achieved (by heat diffusion) in the close proximity of the directly laser-irradiated region, which gives place to the formation of the intermediate non-stoichiometric oxide o-Mo₄O₁₁.

Thermally obtained metallic oxides such as TiOₓ, ZnOₓ, BiOₓ, WOₓ and MoOₓ have been studied extensively showing that those kinds of oxides are usually photochromic³⁰, and/or electrochromic^{31, 32}, and or gasochromic³³. Based on some of these properties of metallic oxides a variety of technological applications have been either suggested or demonstrated, such as optically based gas sensors, transducer based gas sensors, and optically recording devices for storage^{33, 34, 35}. It has also been demonstrated that the electrical features, say the resistivity, of a metallic oxide can be modified by exposing it to femtosecond laser pulses³⁶. On the applied side of the work presented here, we must note that the study and characterization of both the electrical and the optical properties of the fs laser-induced MoOₓ is currently underway within our research group.

According with the above, we demonstrated for the first time, the transformation of metallic molybdenum, zinc, bismuth, titanium, tungsten, and other transition metals into a complex pattern of metal oxides by using very low energy femtosecond, picosecond, and nanosecond laser pulses delivered at a very high repetition rate. Both laser-induced oxidation and crystalline-crystalline phase transformation was achieved, on as-deposited (1 1 0) cubic-molybdenum thin films, by using low energy (nJ)-high repetition rate (MHz) femtosecond pulses. Our results show solid evidence of the transformation from c-Mo into m-MoO₂ and o-Mo₄O₁₁.

According to the present invention, the m-MoO₂ forms along the directly laser-exposed trace and its close proximity, which extends 5 μm sideways and looks light-gray under optical microscope imaging; the o-Mo₄O₁₁ forms a dark-green stripe ˜2 μm wide, right beside the m-MoO₂ trace. There is a complex color pattern formed, as a result of the fs-laser exposure, which includes, from center of the trace outwards: light-gray, light green, dark-green, green, blue, dark-brown, and light-brown. Neither the stoichiometry nor the phase has been identified yet for these colored regions, but those of the light-gray (m-MoO₂) and dark-green (o-Mo₄O₁₁). A detailed Raman study to identify the types of Mo oxide and stoichiometry of the remaining of the colored pattern is underway within our research group.

The process of the present invention comprising the exposure of metallic layers to laser pulses to generate metal oxides, probes to be an efficient and rapid way of obtaining metal oxides, for example molybdenum, in the form of microstructured patterns. Using a beam laser highly focused, it is feasible to obtain an on demand for example a micro-pattern MoOₓ induced by laser, i.e. to selectively obtain a micro pattern made up by stripes of molybdenum dioxide and intermediate oxides up to molybdenum trioxide. The oxides obtained by the process of the present invention could find applications in technology areas as gas sensing, where metal oxides have proved useful given their photochromic, gasochromic, and electrochromic features.

According to the present invention, we present the effect of exposing thin films of transition metals at low energy laser pulses (nJ) and at high repetition (kHz-MHz). Laser used as excitation source in the process of the present invention produce pulses ranging from femtoseconds to nanoseconds. With this process it was possible to achieve laser-induced oxidation of metal thin films, such for example as molybdenum, using a per pulse fluence of 0.03 J/cm². Optical microscopy analysis and scanning electron microscopy (SEM) allowed us to study color and morphology changes in the exposed areas, while energy dispersive spectrometry (EDS) and micro-Raman spectroscopy (MRS) were used to study the stoichiometry and phase transition obtained after laser exposure. The present invention shows that the laser ablation threshold of metal thin films, e.g., molybdenum, occurs at a lower fluence than previously reported in the literature^{37.} It also demonstrates that it is fairly easy to obtain metal oxides with various structures, for example m-MoO₂ and o-Mo₄O₁₁ in the case of molybdenum, as described above. EDS and micro-Raman spectroscopy showed that the transformation of metallic material induced by femtosecond laser follows a spatial resolved profile transverse to the laser scanned direction.

### REFERENCES

### 1. T. Chu-Chi, et. al. 2002. Thin Solid Films, 402, p 290.

2. Perez del Pino, et. al. 2002. Coloring of titanium by pulsed laser processing in air, Thin Solid Films, 415, p 201-205.
3. Qizhi Dong, et. al. 2002. Surface morphology study on chromium oxide growth on Cr films by Nd-YAG laser oxidation process, Applied Surface Science, 202, p 114-119.
4. X. D. Guo, et. al. 2007. Sun, Raman spectroscopy and luminescent properties of ZnO nanostructures fabricated by femtosecond laser pulses, Materials letters, 61, p 4583-4586.
5. Tatsuura, Satoshi, et. al. 2002. Method for electrodeposited film formation, method for electrode formation, and apparatus for electrodeposited film formation. U.S. Pat. No. 6,365,027.
6. Hong, Noh Jun, et. al. 2012. Method of forming nano-structure using pulsed laser deposition and electrode having the nano-structure. KR20120000422.
7. Osada, Takashi. 2006. Oxide-based laminated thin film and method for manufacturing same, and optical device. JP2003276757.
8. Matsunawa, Akira, et. al. . 1988. A method for producing amorphous metal layer. EP0273547.

### 9. G. Mestl, et. al. . 1995. Langmuir, 11, p 3795.

10. D. Luca, L. S., Hsu, J2003. Optoelectron. Adv. Mater. 5, p 835.

### 11. Salazar-Perez, A. J., et. al. . 2005. Superficies Vacio, 18, p 4.

12. Camacho-Lopez, M. A., et. al. . 2006. Mater. Sci. Eng. B, 135, p 88.
13. Matthias, E., et. al. . 1994. Appl. Phys. A, 58, p 126.
14. Jimenez-Perez, J. L., et. al. . 2001. Appl. Surf. Sci., 175-176, p 703.
15. Eaton, S. M., et. al. . 2005. Opt. Express, 13, p 4708.

### 16. Srivastava, R., et. al. . 1972. Solid State Commun., 11, p 349.

17. Camacho-Lopez, M. A., et. al. . 2011. Opt. Mater., 33, p 480.
18. Spevack, P. A., et. al. . 1993. J. Phys. Chem., 97, p 11020.
19. Dieterle, M., et. al. . 2002. Phys. Chem. Chem. Phys., 4, p 812.
20. Dieterle, M. et. al. . 2002. Phys. Chem. Chem. Phys. 4, p 822.

### 21. Blume, A. 2004. PhD Tesis, Technischen Universitat Berlin.

### 22. Mestl, G., et. al. . 1995. Langmuir, 11, p 3795.

23. Byskov-Nielsen, J., et. al. . 2010. Appl. Phys. A, 101, p 97.
24. Ashkenasi, D., et. al. . 2000. Appl. Surf. Sci., 154-155, p 40.
25. Hashida, M., et. al. . 2002. Appl. Sur. Sci., 197-198, p 862.

### 26. Hashida, M. 2007. Science and Technology Created by Ultra-Short, Ultra-High-Peak Power Lasers, Transworld Research Network, Kerala, India.

27. Floquet, N., et. al. . 1992. Oxid. Met., 37, p 253.
28. Zhang, C., et. al. . 1985. Surf. Sci., 149, p 326.
29. Hari Krishna, K., et. al. . 2008. Res. Lett. Nanotechnol., 217510.
30. Belanger, D., et. al. . 1990. Chem. Mater., 2, p 484.

### 31. Chao-Sheng, H., et. al. . 2008. Thin Solid Films, 516, p 4839.

32. Georg, A., et. al. . 2001. Electrochim. Acta, 46, p 2001.
33. Lazcano-Hernandez, H. E., et. al. . 2008. J. Opt. A: Pure Appl. Opt., 10, p 104016.
34. Comini, E., et. al. . 2005 Chem. Phys. Lett., 407, p 368.

### 35. Aoki, T., et. al. . 2008. Thin Solid Films, 517, p 1482.

36. Tsukamoto, M., et. al. . 2008. Appl. Phys. A, 93, p 193.
37. Hermann, J., et. al. . 2006. Appl. Surf. Sci., 252, p 4814.

1-22. (canceled)

23. A process for obtaining metallic oxides by irradiation of metal films with low energy laser pulses, wherein the process comprises the steps of:
a) depositing a metal film on a substrate,
b) irradiating at least a portion of the surface of said metal film with ultrashort laser pulses at a very high repetition rate and having a pulse duration ranging from nanoseconds to picoseconds, and
c) forming of periodic structures of crystalline metallic oxides
wherein said metal film comprises a ring or stripes pattern with a size of tens of micrometers in diameter, and from 2 to 5 micrometers wide.

24. The metallic oxide film of claim 23, wherein said film comprises fine patterns of m-XO, non-stoichiometric patterns of o-XO, a-XO crystalline phases, and combinations thereof, where X is a metal.

25. The metallic oxide film of claim 24, wherein X is selected from the group comprising transition metals, metals of the III A group (Al, Ga, In, Ti), metals of the IV A group (Ge, Sn), metals of the V A group (Bi), or a combination thereof.

26. The metallic oxide film of claim 24, wherein X is selected from the group comprising Mo, Ti, W, Sn, Bi, Zn, and combinations thereof.

27. The metallic oxide film of claim 26, wherein the patterns comprise MoO₂, TiO₂, WO₃, SnO₂, Bi₂O₃, and ZnO.

28. The metallic oxide film of claim 25, wherein X is Mo and the patterns comprise m-MoO₂fine pattern, non-stoichiometric o-Mo₄O₁₁ pattern, and a-MoO₃ crystalline phase.
